(19) United States
(12) Patent Application Publication
(10) Pub. No.: US 2026/0354110 A1
(43) Pub. Date: Nov. 5, 2026

(54) LIFT PINS, CHAMBER ARRANGEMENTS INCLUDING LIFT PINS, AND METHOD FOR FORMING LIFT PINS

(71) Applicant: ASM IP Holding B.V., Almere (NL)

(72) Inventors: Qichao Hu, Tempe, AZ (US); Junwei Su, Chandler, AZ (US); Fan Gao, Chandler, AZ (US); Shaofeng Chen, Austin, TX (US); Chuwei Chen, Tempe, AZ (US); Wentao Wang, Chandler, AZ (US); Ion Hong Chao, Gilbert, AZ (US); Shujin Huang, Phoenix, AZ (US); Jingxuan Lyu, Chandler, AZ (US); Han Ye, Phoenix, AZ (US); Sipan Liu, Tempe, AZ (US); Yu-Jung Chen, Scottsdale, AZ (US); Bowei Li, Phoenix, AZ (US)

(21) Appl. No.: 19/661,821

(22) Filed: Apr. 29, 2026

Related U.S. Application Data
(60) Provisional application No. 63/798,722, filed on May 2, 2025.

(51) Int. Cl. H10P 72/76; C23C 16/458

(52) U.S. Cl. CPC H10P 72/7612; C23C 16/4581; H10P 72/7616

(57) ABSTRACT

A lift pin for semiconductor processing systems is provided, featuring a body constructed from glassy carbon with a base, stem segment, and contact tip. A silicon carbide coating is applied to at least the stem segment. Additionally, a chamber arrangement is provided, where the lift pin is utilized within a chamber body, designed to support a substrate during material layer deposition. A substrate support within the chamber arrangement includes a susceptor structure with a silicon carbide-coated body, where the coating is thicker than that on the lift pin. Also provided is a method for creating the lift pin.

### CROSS-REFERENCE TO RELATED APPLICATIONS

This application is a nonprovisional of, and claims priority to and the benefit of, U.S. Provisional Patent Application No. 63/798,722, filed May 2, 2025 and entitled “LIFT PINS, CHAMBER ARRANGEMENTS INCLUDING LIFT PINS, AND METHOD FOR FORMING LIFT PINS,” which is hereby incorporated by reference herein.

### FIELD

The present disclosure relates generally to the field of semiconductor processing systems and associated sub-systems and methods, and to the field of device and integrated circuit manufacture. More particularly, exemplary embodiments of the present disclosure relate to lift pins and to chamber arrangements including lift pins.

### BACKGROUND

Gas-phase reactors for processing substrates, such as semiconductor wafers, often include a substrate support, such as a susceptor, for example, within a reaction chamber. During processing, one or more substrates are placed within the reaction chamber and onto the substrate support using a robotic arm. After processing, the substrate(s) are removed from the surface of the substrate support and through an opening in the reaction chamber using the robotic arm.

During the substrate transfer process, lift pins, which extend through a vertical width of the susceptor and beyond, can be used to facilitate placement and removal of the substrate on and from the surface of the susceptor. In such cases, a substrate can be placed onto the susceptor by causing the lift pins to rise above the surface of the susceptor, placing the substrate onto the lift pins, and lowering the lift pins, such that the substrate rests on the susceptor.

The susceptor and the lift pins are often formed of different materials. Because of differences in emissivity, heat conductance, and/or heat capacity of the different susceptor and lift pin materials, hot or cold spots can form on a substrate overlying the susceptor in the locations of the lift pins. The hot or cold spots can cause deposition or etch rates of material on a surface of the substrate in the area of the lift pins to be different (higher or lower) than areas away from the lift pin. In addition, use of such different materials can lead to lift pins “sticking” or even adhering to the susceptor. Accordingly, improved lift pins and apparatus including such lift pins are desired.

Any discussion, including discussion of problems and solutions, set forth in this section, has been included in this disclosure solely for the purpose of providing a context for the present disclosure, and should not be taken as an admission that any or all of the discussion was known at the time the disclosure was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

In accordance with examples of the disclosure, a lift pin is disclosed, the lift pin comprising: a lift pin body defining a body axis and formed from a glassy carbon material, the lift pin body having: a base extending about the body axis, a stem segment extending axially from the base, and a contact tip coupled to the base by the stem segment. The lift pin further comprises a silicon carbide coating formed onto at least the stem segment of the lift pin body, the silicon carbide coating having an average thickness between 20 microns and 50 microns.

In some embodiments, the silicon carbide coating has an average thickness between 20 microns and 40 microns.

In some embodiments, the silicon carbide coating has an average thickness between 30 microns and 50 microns.

In some embodiments, the silicon carbide coating has a surface roughness (Ra) between about 0.2 and about 0.8.

In some embodiments, the silicon carbide coating has a surface roughness (Ra) less than about 0.8.

In some embodiments, the silicon carbide coating has a surface roughness (Ra) less than about 0.2.

In some embodiments, the silicon carbide coating has a surface roughness (Ra) less than about 0.05.

In some embodiments, the silicon carbide coating has an average thickness between 20 microns and 40 microns, and a surface roughness (Ra) between about 0.2 and about 0.8.

In some embodiments, the silicon carbide coating has an average thickness between 20 microns and 40 microns, and a surface roughness (Ra) less than 0.8.

In some embodiments, the silicon carbide coating has an average thickness between 20 microns and 40 microns, and a surface roughness (Ra) less than 0.2.

In some embodiments, the silicon carbide coating has an average thickness between 20 microns and 40 microns, and a surface roughness (Ra) less than 0.05.

In some embodiments, the silicon carbide coating has an average thickness between 20 microns and 40 microns, or between 30 microns and 50 microns, and has a surface roughness (Ra) between about 0.2 and about 0.8.

In some embodiments, the silicon carbide coating has a percent thickness non-uniformity of less than 50%.

In accordance with examples of the disclosure, a chamber arrangement is disclosed, the chamber arrangement comprising: a chamber body formed from a quartz material, a substrate support arranged within an interior of the chamber body and configured to support a substrate during deposition of a material layer onto the substrate, and a lift pin slidably received within a lift pin aperture extending through the substrate support. In such chamber arrangements, the lift pin comprises: a lift pin body defining a body axis and formed from a glassy carbon material, the lift pin body having a base extending about the body axis, a stem segment extending axially from the base, and a contact tip coupled to the base by the stem segment, and a first silicon carbide coating formed onto at least the stem segment of the lift pin body and having an average thickness between 20 microns and 50 microns, and a surface roughness (Ra) between about 0.2 and about 0.8, the substrate support including a susceptor structure having a susceptor body coated with a second silicon carbide coating, a ratio of the average thickness of the second silicon carbide coating to the first silicon carbide coating being greater than 1:1.

In some embodiments, the chamber arrangement includes a substrate support comprising a susceptor structure having a susceptor body coated with a second silicon carbide coating and a ratio of the average thickness of the second silicon carbide coating to the first silicon carbide coating is greater than 1:1. In some embodiments, the ratio of the average thickness of the second silicon carbide coating to the first silicon carbide coating is greater than 1.5:1. In some embodiments, the ratio of the average thickness of the second silicon carbide coating to the first silicon carbide coating is between 1:1 and 5:1.

In accordance with examples of the disclosure, a semiconductor processing system is disclosed, the semiconductor processing system including the chamber arrangements and lift pins as provided here.

In accordance with examples of the disclosure, a method of making a lift pin for a semiconductor processing system is disclosed, the method comprising: providing a lift pin body defining a body axis and formed from a glassy carbon material, the lift pin body having a base extending about the body axis, a stem segment extending axially from the base, and a contact tip coupled to the base by the stem segment; and forming a silicon carbide coating on at least the stem segment of the lift pin body; wherein the silicon carbide coating has an average thickness between 20 microns and 50 microns, and a surface roughness (Ra) between about 0.2 and about 0.8.

In some embodiments, the silicon carbide coating comprises a multilayer silicon carbide coating formed by performing two or more repeating silicon carbide deposition processes.

In some embodiments, the multilayer silicon carbide coating has a percentage thickness non-uniformity of less than 50%.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary lift pin in accordance with one or more embodiments of the disclosure.

FIG. 2 illustrates a cross-sectional view of a lift pin in accordance with one or more embodiments of the disclosure.

FIG. 3 illustrates an additional exemplary lift pin in accordance with one or more embodiments of the disclosure.

FIG. 4 illustrates a further exemplary lift pin in accordance with one or more embodiments of the disclosure.

FIG. 5 illustrates a schematic view of a chamber arrangement including a lift pin in accordance with one or more embodiments of the disclosure.

FIG. 6 illustrates a schematic view of a semiconductor processing system including a chamber arrangement having lift pins in accordance with one or more embodiments of the disclosure.

FIG. 7 illustrates an exemplary method 700 for forming lift pins in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

In the specification, it will be understood that the term “on” or “over” may be used to describe a relative location relationship. Another element, film or layer may be directly on the mentioned layer, or another layer (an intermediate layer) or element may intervene therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood that the terms “under”, “underlying”, or “below” will be construed to be relative concepts.

The present disclosure generally relates to lift pins and assemblies including the lift pins. As set forth in more detail below, the lift pins and the assemblies can be used in the manufacturing of devices, such as devices formed using semiconductor substrates.

Commonly employed lift pins can be problematic for a number of reasons. For example, prior lift pins may become contaminated with residue or debris during deposition processes, which can result in the lift pins becoming “stuck” or even adhered to the substrate support (e.g., a susceptor). In addition, prior lift pins can cause radiative losses when they are heated, as they can act as radiators, emitting heat into the surrounding environment. This can lead to a loss of heat from the reaction chamber, causing temperature non-uniformities on the substrate closest to the lift pins. As a result, a material layer deposited on the substrate in contact with the lift pins can have non-uniform properties, as some areas may be heated more than others, potentially resulting in defects, inhomogeneities, and reduced yield.

A lift pin can be configured as a hybrid lift pin including an inner portion formed from a material having a relatively low thermal conductivity and a shell portion formed from a material having a relatively high hardness and relatively low friction. Such a hybrid lift pin can be configured as a high emissivity lift pin that maintains a balance between pin binding prevention and reduction of pin artifact. For example, a low thermal conductivity inner portion can reduce temperature disturbance at a substrate during processing, while a high hardness shell can increase pin binding margin and reduce friction relative to the inner-portion material.

Inner-portion material and shell material for a hybrid lift pin can be selected based on one or more material properties including density, flexural strength, compressive strength, hardness, maximum use temperature, thermal conductivity, coefficient of thermal expansion, and transparency. A selected inner-portion material can provide reduced thermal conductivity relative to a selected shell material, while the selected shell material can provide increased hardness relative to the selected inner-portion material. The selected shell material also can be chosen to provide improved wear resistance, reduced friction, or increased pin binding margin.

In some embodiments, a hybrid lift pin includes a fused quartz inner portion and a boron carbide coating. The fused quartz inner portion can provide improved thermal sink performance relative to some other inner-portion materials and can be transparent, while the boron carbide coating can provide increased hardness and can be non-transparent. Relative to a silicon carbide coated glassy carbon lift pin, a boron carbide coated fused quartz lift pin can provide improved bending strength and thermal conductivity. Such a lift pin may be used in a boron deposition chamber and may be less suitable for a chamber having silicon deposition.

In some embodiments, a hybrid lift pin includes a glassy carbon inner portion and a chemical vapor deposited diamond coating. The glassy carbon inner portion can provide improved pin artifact performance, while the chemical vapor deposited diamond coating can provide improved pin binding performance. Relative to a silicon carbide coated glassy carbon lift pin, a chemical vapor deposited diamond coated glassy carbon lift pin can provide improved pin binding performance and improved pin artifact performance. Manufacture of a chemical vapor deposited diamond coated glassy carbon lift pin may be more difficult than manufacture of a silicon carbide coated glassy carbon lift pin.

In some embodiments, a hybrid lift pin includes a glassy carbon inner portion and a diamond-like carbon coating. The glassy carbon inner portion can provide improved pin artifact performance, while the diamond-like carbon coating can provide improved pin binding performance. Relative to a silicon carbide coated glassy carbon lift pin, a diamond-like carbon coated glassy carbon lift pin can provide improved pin binding performance and improved pin artifact performance. A diamond-like carbon coated glassy carbon lift pin may be employed in applications having a temperature within a temperature capability of the diamond-like carbon coating and may be less suitable for relatively high temperature applications.

Accordingly, various embodiments of the present disclosure relate to lift pins having properties designed to alleviate the issues described above. As such, the lift pins of the present disclosure can include a lift pin body formed from a first material and configured to alleviate issues relating to lift pin heating, and a second material coating the first material (and different from the first material) configured to alleviate issues relating to lift pin sticking and/or adherence to a substrate support. As described in greater detail below, the lift pins disclosed herein can comprise a glassy carbon body to resolve heat related pin artifact issues. In addition, by coating the glassy carbon pin body with a thin layer of silicon carbide (SIC), damage to the pin body surface from a susceptor can be prevented or substantially reduced. Additionally, since a SiC layer can also be used as a coating for a susceptor, the lift pins of the present disclosure can reduce damage to the susceptor, thereby relieving the pin binding issue. Further, when employing a thin SiC layer it has negligible thermal mass, which can ensure that the silicon carbide coating does not contribute to further heating related issues.

The description of exemplary embodiments of lift pins and assemblies provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

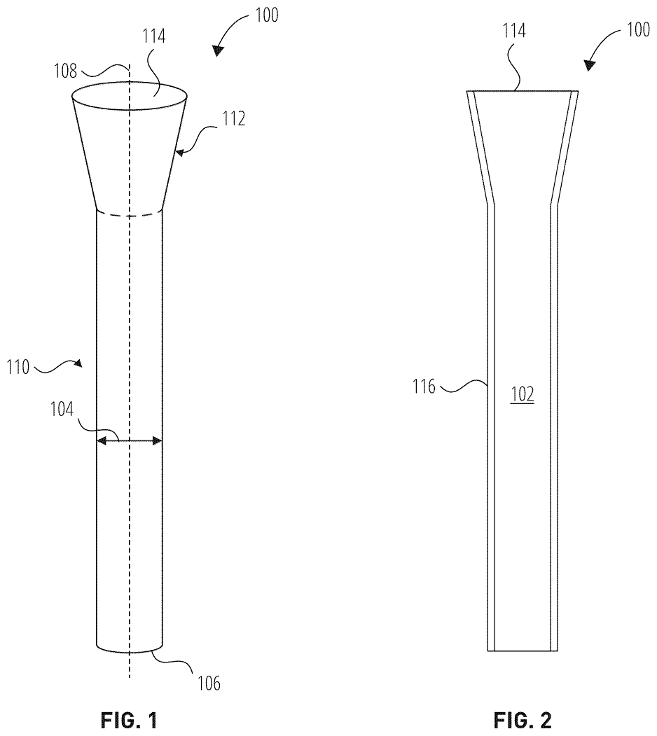

Turning now to the figures, FIG. 1 illustrates an exemplary lift pin 100 of the present disclosure and FIG. 2 illustrates a cross-sectional view of the lift pin 100 through the body axis 108.

In various embodiments, the lift pin 100 comprises a lift pin body 102 defining a body axis 108. For example, the lift pin body 102 can define (or can arranged along) the body axis 108 and is configured to be slidably received within a lift pin aperture extending through a substrate support, as described below. The lift pin body 102 has a body diameter 104 as illustrated in FIG. 1.

The lift pin body can be formed from suitable opaque materials. Examples of suitable opaque materials include ceramic materials, such as silicon carbide, as well as carbonaceous materials such as glassy carbon materials. In certain examples, the lift pin body is formed from a glassy carbon material. In such examples, the glassy carbon material may be selected for the lift pin body 102 to limit temperature variation across a substrate, promoting uniformity of the material layer during semiconductor processing. The lift pin body 102 includes a base 106 extending about the body axis. A stem segment 110 extends axially from the base 106. The lift pin body 102 further comprises a contact tip 112 coupled to the base 106 by the stem segment 110. The contact tip 112 can include a contact pad 114.

The silicon carbide coating 116 may extend over the stem segment 110 and over at least a portion of the contact tip 112. The silicon carbide coating 116 also may cover a pin head of the lift pin body 102. In other embodiments, the silicon carbide coating 116 may have an average thickness of less than 20 microns, such as about 7 microns or about 10 microns, and can be selected to provide increased surface hardness while maintaining desired thermal performance of the lift pin body 102.

In various embodiments, lift pin 100 includes a silicon carbide coating that is formed at least partially onto the stem segment of the lift pin body. An exemplary silicon carbide coating is illustrated in FIG. 1, where the silicon carbide coating 116 is formed onto the stem segment 110 of the lift pin body 102. In some embodiments, the silicon carbide coating 116 extends over at least a portion of the contact tip 112. In other embodiments, the contact pad 114 can remain free of the silicon carbide coating.

In some embodiments, the silicon carbide coating 116 has an average thickness between 20 microns and 50 microns. In some embodiments, the silicon carbide coating 116 has an average thickness between 20 microns and 40 microns. In some embodiments, the silicon carbide coating 116 has an average thickness between 30 microns and 50 microns.

In some embodiments, the silicon carbide coating 116 has a surface roughness (Ra) between about 0.2 and about 0.8. In some embodiments, the silicon carbide coating has a surface roughness (Ra) less than about 0.8. In some embodiments, the silicon carbide coating has a surface roughness (Ra) less than about 0.2. In some embodiments, the silicon carbide coating has a surface roughness (Ra) less than about 0.05.

In some embodiments, the silicon carbide coating 116 has an average thickness between 20 microns and 50 microns, and a surface roughness (Ra) between about 0.2 and about 0.8. In some embodiments, the silicon carbide coating 116 has an average thickness between 20 microns and 50 microns, and a surface roughness (Ra) less than 0.8. In some embodiments, the silicon carbide coating 116 has an average thickness between 20 microns and 50 microns, and a surface roughness (Ra) less than 0.2. In some embodiments, the silicon carbide coating 116 has an average thickness between 20 microns and 50 microns, and a surface roughness (Ra) less than 0.05.

In some embodiments, the silicon carbide coating 116 has an average thickness between 20 microns and 40 microns, and a surface roughness (Ra) between about 0.2 and about 0.8. In some embodiments, the silicon carbide coating 116 has an average thickness between 20 microns and 40 microns, and a surface roughness (Ra) less than 0.8. In some embodiments, the silicon carbide coating 116 has an average thickness between 20 microns and 40 microns, and a surface roughness (Ra) less than 0.2. In some embodiments, the silicon carbide coating 116 has an average thickness between 20 microns and 40 microns, and a surface roughness (Ra) less than 0.05.

In some embodiments, the silicon carbide coating 116 has an average thickness between 30 microns and 50 microns, and a surface roughness (Ra) between about 0.2 and about 0.8. In some embodiments, the silicon carbide coating 116 has an average thickness between 30 microns and 50 microns, and a surface roughness (Ra) less than 0.8. In some embodiments, the silicon carbide coating 116 has an average thickness between 30 microns and 50 microns, and a surface roughness (Ra) less than 0.2. In some embodiments, the silicon carbide coating 116 has an average thickness between 30 microns and 50 microns, and a surface roughness (Ra) less than 0.05.

In some embodiments, the silicon carbide coating 116 has a percentage thickness non-uniformity (NU %) of less than 50%, less than 40%, less than 30%, less than 20%, less than 10%, less than 5%, less than 3%, less than 2%, less than 1%, less than 0.8%, less than 0.5%.

In some embodiments, the silicon carbide coating 116 has an average thickness between 20 microns and 50 microns, and a percentage thickness non-uniformity (NU %) of less than 50%, less than 40%, less than 30%, less than 20%, less than 10%, less than 5%, less than 3%, less than 2%, less than 1%, less than 0.8%, less than 0.5%.

In some embodiments, the silicon carbide coating 116 has an average thickness between 20 microns and 40 microns, and a percentage thickness non-uniformity (NU %) of less than 50%, less than 40%, less than 30%, less than 20%, less than 10%, less than 5%, less than 3%, less than 2%, less than 1%, less than 0.8%, less than 0.5%.

In some embodiments, the silicon carbide coating 116 has an average thickness between 30 microns and 50 microns, and a percentage thickness non-uniformity (NU %) of less than 50%, less than 40%, less than 30%, less than 20%, less than 10%, less than 5%, less than 3%, less than 2%, less than 1%, less than 0.8%, less than 0.5%.

In some embodiments, the silicon carbide coating 116 has an average thickness between 20 microns and 50 microns, a percentage thickness non-uniformity (NU %) of less than 50%, less than 40%, less than 30%, less than 20%, less than 10%, less than 5%, less than 3%, less than 2%, less than 1%, less than 0.8%, less than 0.5%, and a surface roughness (Ra) between about 0.2 and about 0.8. In some embodiments, the silicon carbide coating 116 has an average thickness between 20 microns and 50 microns, a percentage thickness non-uniformity (NU %) of less than 50%, less than 40%, less than 30%, less than 20%, less than 10%, less than 5%, less than 3%, less than 2%, less than 1%, less than 0.8%, less than 0.5%, and a surface roughness (Ra) less than 0.8. In some embodiments, the silicon carbide coating 116 has an average thickness between 20 microns and 50 microns, a percentage thickness non-uniformity (NU %) of less than 50%, less than 40%, less than 30%, less than 20%, less than 10%, less than 5%, less than 3%, less than 2%, less than 1%, less than 0.8%, less than 0.5%, and a surface roughness (Ra) less than 0.2. In some embodiments, the silicon carbide coating 116 has an average thickness between 20 microns and 50 microns, and a surface roughness (Ra) less than 0.05.

In some embodiments, the silicon carbide coating 116 is formed conformally over the lift pin body 102. In certain examples, the silicon carbide coating 116 is formed over the lift pin body 102 with a step coverage greater than 85%, or greater than 90%, or greater than 95%, or greater than 97%, or greater than 98%, or greater than 99%, or substantially equal to 100%, or between 80% and 100%.

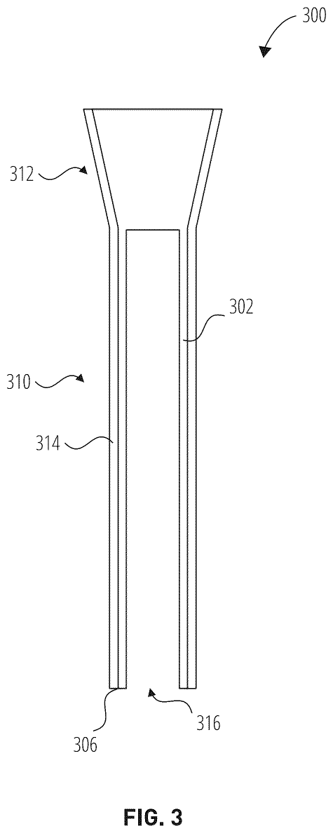

FIG. 3 illustrates an exemplary lift pin 300 of the present disclosure. In various embodiments, the lift pin 300 comprises the features, properties (e.g., thicknesses, surface roughness, etc.) of lift pin 100 but includes a body cavity 316 disposed within the lift pin body 302, the lift pin body being coated with a silicon carbide coating 314. In some embodiments, the body cavity 316 extends from the base 306 to a location proximate to the contact tip 312. In certain examples, the body cavity 316 extends from the base 306 to a location proximate to the intersection between the stem segment 310 and the contact tip 312.

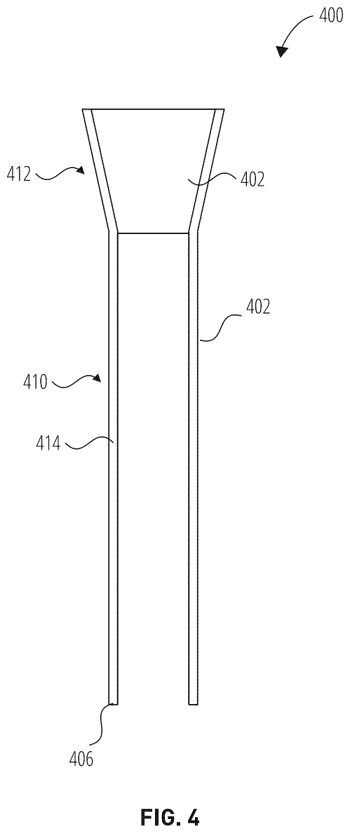

FIG. 4 illustrates an exemplary lift pin 400 of the present disclosure. In various embodiments, the lift pin 400 comprises the features, properties (e.g., thicknesses, surface roughness, etc.) of lift pin 100 but comprises a reduced lift pin body 402, the lift pin body 402 being coated with a silicon carbide coating 414. In certain examples, the lift pin body 402 comprises the contact tip 412 portion of the lift pin body, as illustrated in FIG. 4.

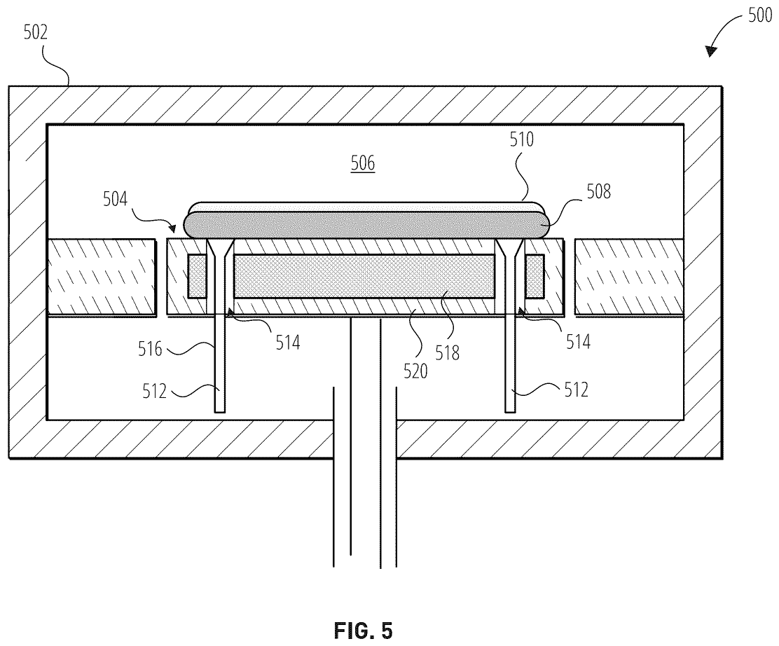

The embodiments of the disclosure provide chamber arrangements including the lift pins (e.g., 100, 300, and 400). FIG. 5 illustrates a schematic view of a chamber arrangement 500. The chamber arrangement 500 comprises a chamber body 502 formed from a transparent material, such as a quartz material, for example. A substrate support 504 is arranged within an interior 506 of the chamber body 502 and is configured to support a substrate 508 during deposition of a material layer 510 onto the substrate 508. One or more lift pins 512 (e.g., lift pins 100, 300, 400 of FIGS. 1-4) can be slidably received within a lift pin aperture 514 extending through the substrate support 504. As previously described above, the lift pin can comprise a lift pin body defining a body axis and formed from a glassy carbon material, the lift pin body having a base extending about the body axis, a stem segment extending axially from the base, and a contact tip coupled to the base by the stem segment, and a first silicon carbide coating formed onto at least the stem segment of the lift pin body and having an average thickness between 20 microns and 50 microns, and a surface roughness (Ra) between about 0.2 and about 0.8. In some embodiments, the substrate support 504 comprises a susceptor structure having a susceptor body 518 coated with a second silicon carbide coating 520.

In some embodiments, a ratio of the average thickness of the second silicon carbide coating 520 to the first silicon carbide coating 116 is greater than 1:1.

In some embodiments, the ratio of the average thickness of the second silicon carbide coating to the first silicon carbide coating is greater than 2:1.

In some embodiments, the ratio of the average thickness of the second silicon carbide coating to the first silicon carbide coating is between 1:1 and 5:1.

In some embodiments, the ratio of the average thickness of the second silicon carbide coating to the first silicon carbide coating is between 1:1 and 3:1.

In some embodiments, the ratio of the average thickness of the second silicon carbide coating to the first silicon carbide coating is between 1:1 and 2:1.

In some embodiments, the ratio of the average thickness of the second silicon carbide coating to the first silicon carbide coating is between 1:1 and 1.5:1.

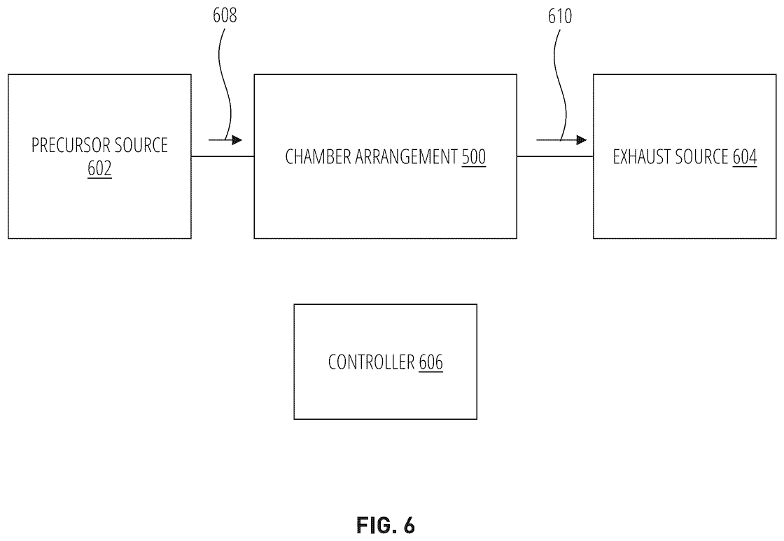

The embodiments of the disclosure provide semiconductor processing systems including both the chamber arrangements (e.g., 500) and the lift pins (e.g., 100, 300, and 400), as described above. FIG. 6 illustrates a schematic view of a semiconductor processing system 600 including a precursor source 602 configured for supplying one or more precursor gases (as indicated by precursor flow 608) to the chamber arrangement 500, the chamber arrangement being in fluid communication with an exhaust source 604 configured for removing exhaust gas (as indicated by exhaust flow 610). A controller 606 can be operably coupled to the precursor source 602, the chamber arrangement 500, and the exhaust source 604 to provide control and operational instructions to enable deposition of a material layer.

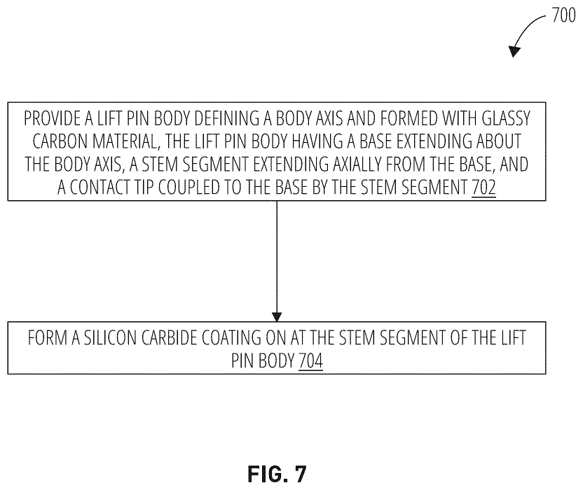

The embodiments of the disclosure provide methods of making a lift pin for a semiconductor processing system. FIG. 7 illustrates an exemplary method 700. At step 702, method 700 provides a lift pin body defining a body axis and formed from a glassy carbon material, the lift pin body having a base extending about the body axis, a stem segment extending axially from the base, and a contact tip coupled to the base by the stem segment. At step 704, method 700 forms a silicon carbide coating on at least the stem segment of the lift pin body, where the silicon carbide coating has an average thickness between 20 microns and 50 microns, and a surface roughness (Ra) between about 0.2 and about 0.8.

In some embodiments, the silicon carbide coating comprises a multilayer silicon carbide coating formed by performing two or more repeating silicon carbide deposition processes. In such embodiments, step 704 of forming the silicon carbide coating can comprise two or more repeated chemical vapor deposition processes. In such embodiments, step 704 of forming the silicon carbide coating can comprise two or more repeated deposition cycles of an atomic layer deposition process. In some embodiments, step 704 of forming the silicon carbide coating can comprise 2 or more, 3 or more, 4 or more, 5 or more, 6 or more, 7 or more, 8 or more, or 10 or more silicon carbide deposition processes. In such embodiments, each individual silicon carbide deposition process (e.g., cycle) can deposit a portion of the total thickness of the silicon carbide coating. In certain examples, each individual silicon carbide deposition process can deposit an average layer thickness of less than 25 microns, less than 20 microns, less than 15 microns, less than 10 microns, less than 8 microns, less than 6 microns, less than 5 microns, or between 5 microns and 25 microns. In certain examples, a multilayer silicon carbide coating may be employed to attain the desired properties of the silicon carbide coating, such as, for example, the surface roughness (Ra), the average silicon carbide layer thickness, and the step coverage, as described above. In one aspect, the multilayer silicon carbide coating can be deposited by method 700 to attain one or more, or all of the silicon carbide properties as previously described above.

A plurality of lift pin fixture configurations may be used during formation of the silicon carbide coating 116. For example, three different fixture configurations can be developed for silicon carbide coating of lift pins and can be identified as Group A, Group B, and Group C configurations. The Group A configuration can provide a more uniform coating based on visual inspection than the Group B configuration or the Group C configuration. Lift pins formed using one or more of the fixture configurations can satisfy predetermined drawing requirements before qualification testing.

Evaluation of a hybrid lift pin may include a bench test and an alpha test. The bench test can include about 1000 wafer cycles. An alpha test can include baseline collection for a hybrid lift pin installed in a semiconductor processing chamber before extended process evaluation. Engineering evaluation of a first generation hybrid lift pin can be used to provide feedback for subsequent lift pin development, including development of a lift pin having a silicon carbide coating thickness of about 10 microns.

A hybrid lift pin including a glassy carbon inner portion and a silicon carbide coating can be characterized for surface roughness at a plurality of sections before and after about 1000 wafer cycles. By way of example, for a hybrid lift pin, a baseline surface roughness parameter Ra can be about 0.21 at a first section, about 0.18 at a second section, about 0.12 at a third section, about 0.11 at a fourth section, and about 0.13 at a fifth section, and after about 1000 wafer cycles the surface roughness parameter Ra can be about 0.108 at the first section, about 0.140 at the second section, about 0.120 at the third section, about 0.186 at the fourth section, and about 0.186 at the fifth section.

Surface roughness results for a hybrid lift pin can be compared with surface roughness results for an uncoated glassy carbon lift pin and for a polished silicon carbide lift pin. By way of example, for a glassy carbon lift pin, a baseline surface roughness parameter Ra can be about 0.51, about 0.44, about 0.44, about 0.50, and about 0.48 at first through fifth sections, respectively, and after about 1000 wafer cycles the surface roughness parameter Ra can be about 0.53, about 0.44, about 0.48, about 0.51, and about 0.46 at the first through fifth sections, respectively. For a polished silicon carbide lift pin, a baseline surface roughness parameter Ra can be about 0.11, about 0.12, about 0.10, about 0.08, and about 0.13 at first through fifth sections, respectively, and after about 1000 wafer cycles the surface roughness parameter Ra can be about 0.10, about 0.10, about 0.09, about 0.08, and about 0.11 at the first through fifth sections, respectively.

The silicon carbide coating 116, or any of the alternative coatings disclosed herein, may maintain surface roughness stability after repeated wafer cycling. Surface roughness stability can refer to a condition in which a percentage change in average surface roughness across the surface of the lift pin 100 is less than 15 percent after about 1000 wafer cycles. The average surface roughness can be determined from surface roughness parameter Ra measurements taken at a plurality of sections of the lift pin 100 before and after the about 1000 wafer cycles, and the percentage change in average surface roughness can be determined according to Equation 1:

$$\frac{\vert {Ra}_{avg , after} - {Ra}_{avg , before} \vert}{{Ra}_{avg , before}} \times 100$$

where Ra_{avg,before} is the average surface roughness before the about 1000 wafer cycles and Ra_{avg,after} is the average surface roughness after the about 1000 wafer cycles. In some embodiments, the surface roughness stability across the surface of the lift pin 100 is less than 10 percent, less than 5 percent, less than 2 percent, or even less than 1 percent.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A lift pin, comprising:
a lift pin body defining a body axis and formed from a glassy carbon material, the lift pin body having:
a base extending about the body axis;
a stem segment extending axially from the base; and
a contact tip coupled to the base by the stem segment; and
a silicon carbide coating formed onto at least the stem segment of the lift pin body,
wherein the silicon carbide coating has an average thickness between 20 microns and 50 microns.

2. The lift pin of claim 1, wherein the silicon carbide coating has an average thickness between 20 microns and 40 microns.

3. The lift pin of claim 1, wherein the silicon carbide coating has an average thickness between 30 microns and 50 microns.

4. The lift pin of claim 1, wherein the silicon carbide coating has a surface roughness (Ra) between about 0.2 and about 0.8.

5. The lift pin of claim 1, wherein the silicon carbide coating has a surface roughness (Ra) less than about 0.2.

6. The lift pin of claim 1, wherein the silicon carbide coating has a surface roughness (Ra) less than about 0.05.

7. The lift pin of claim 1, wherein the silicon carbide coating has an average thickness between 20 microns and 40 microns, and a surface roughness (Ra) between about 0.2 and about 0.8.

8. The lift pin of claim 1, wherein the silicon carbide coating has an average thickness between 20 microns and 40 microns, and a surface roughness (Ra) less than 0.2.

9. The lift pin of claim 1, wherein the silicon carbide coating has an average thickness between 20 microns and 40 microns, and a surface roughness (Ra) less than 0.05.

10. The lift pin of claim 1, wherein the silicon carbide coating extends over the contact tip.

11. The lift pin of claim 1, wherein the silicon carbide coating has a percent thickness non-uniformity of less than 50%.

12. The lift pin of claim 1, wherein the silicon carbide coating is configured to maintain coating stability after about 1000 wafer cycles.

13. The lift pin of claim 12, wherein the silicon carbide coating is characterized by surface roughness stability after about 1000 wafer cycles, based on surface roughness parameter (Ra) measurements taken at a plurality of sections of the lift pin before and after the about 1000 wafer cycles, wherein a percentage change in average surface roughness across a surface of the lift pin is less than 15 percent.

14. A chamber arrangement, comprising:
a chamber body formed from a quartz material;
a substrate support arranged within an interior of the chamber body and configured to support a substrate during deposition of a material layer onto the substrate;
a lift pin slidably received within a lift pin aperture extending through the substrate support, the lift pin comprising:
a lift pin body defining a body axis and formed from a glassy carbon material, the lift pin body having:
a base extending about the body axis;
a stem segment extending axially from the base; and
a contact tip coupled to the base by the stem segment; and
a first silicon carbide coating formed onto at least the stem segment of the lift pin body and having an average thickness between 20 microns and 50 microns, and a surface roughness (Ra) between about 0.2 and about 0.8;
wherein the substrate support comprises a susceptor structure having a susceptor body coated with a second silicon carbide coating, a ratio of the average thickness of the second silicon carbide coating to the first silicon carbide coating being greater than 1:1.

15. The chamber arrangement of claim 14, wherein the ratio of the average thickness of the second silicon carbide coating to the first silicon carbide coating is greater than 1.5:1.

16. The chamber arrangement of claim 14, wherein the ratio of the average thickness of the second silicon carbide coating to the first silicon carbide coating is between 1:1 and 5:1.

17. A semiconductor processing system comprising the chamber arrangement of claim 14.

18. A method of making a lift pin for a semiconductor processing system, the method comprising:
providing a lift pin body defining a body axis and formed from a glassy carbon material, the lift pin body having a base extending about the body axis, a stem segment extending axially from the base, and a contact tip coupled to the base by the stem segment; and
forming a silicon carbide coating on at least the stem segment of the lift pin body,
wherein the silicon carbide coating has an average thickness between 20 microns and 50 microns, and a surface roughness (Ra) between about 0.2 and about 0.8.

19. The method of claim 18, wherein the silicon carbide coating comprises a multilayer silicon carbide coating formed by performing two or more repeating silicon carbide deposition processes.

20. The method of claim 19, wherein the multilayer silicon carbide coating has a percentage thickness non-uniformity of less than 50%.
